(19) United States
(12) Patent Application Publication
(10) Pub. No.: US 2007/0259639 A1
(43) Pub. Date: Nov. 8, 2007

(54) Multi-standard module integration

(75) Inventors: Stephen J. Kovacic, Ottawa (CA); Jeremy Loraine, Cottenham (GB)

Correspondence Address: KENYON & KENYON LLP, 1500 K STREET N.W., SUITE 700, WASHINGTON, DC, 20005, US

(73) Assignee: SiGe Semiconductor Inc., Ottawa (CA)

(21) Appl. No.: 11/415,108

(22) Filed: May 2, 2006

(51) Int. Cl. G01R 33/02; H04B 1/06; H04B 1/28; H01L 29/82; G06F 1/00

(52) U.S. Cl. 455/252.1; 324/252; 713/500; 455/333; 257/414; 257/427

(57) ABSTRACT

An electronic module that operates at various radio frequency standards is provided. The module includes a first integrated circuit die formed in a first semiconductor substrate and manufactured using a first semiconductor process. Disposed within the first integrated circuit is the first signal conditioning circuit for performing a function and a first ancillary circuit. The first ancillary circuit electrically coupled to the first signal conditioning circuit for use by the first signal conditioning circuit during operation thereof. Also within the module is a second integrated circuit formed in a semiconductor substrate, disposed within the second integrated circuit is a second signal conditioning circuit. The second signal conditioning circuit being electrically coupled to the first ancillary circuit such that during operation the first ancillary circuit is connected to either one of the first signal conditioning circuits or one of the second signal conditioning circuits. The other than selected conditioning circuit being other than electrically controlled by the first ancillary circuit. The second integrated circuit die benefits from the operation of the first ancillary circuit for performing control, power management and feedback.

### FIELD OF THE INVENTION

The invention relates to the field of RF circuits and more specifically to the field of integration of RF circuits for multiple standard microwave modules.

### BACKGROUND OF THE INVENTION

Typically, manufacturers in the area of wireless products wish to implement radio media interface circuits into radio terminals, such as PCMCIA cards or dongles, which operate within the context of two or more radio standards but in accordance with one standard at any one time. These radio standards are for example collectively referred to as the IEEE 802 standard, which is well known to those of skilled in the art. This standard is typically divisible into a number of individual radio standards including one standard at 5.8 GHz, known as 802.11a, and another two standards at 2.45 GHz, known as 802.11b and 802.11g.

In terms of these radio standards, manufacturers are often interested in building radio terminals that are able to operate with any of the 802.11a, b, and g standards, thereby giving maximum coverage and flexibility to the users or applications accessing the radio terminal. Importantly, only one particular standard is active at any one time. As a result, the manufacturers are interested in acquiring a front-end module that incorporates receive and transmission elements such as the low noise amplifiers (LNA), power amplifiers (PA), impedance matching components, and RF switches for all the standards that the terminal or card could deal with. Thus providing them with flexibility in their radio terminal designs.

Unfortunately, PAs and other components such as the LNA are highly specialized components that have specifications that generally do not overlap with other radio frequency bands. Thus, a 5.8 GHz PA is generally not suitable for use as a 2.4 GHz PA. As a result, distinct components such as the LNAs and PAs are incorporated into the module in order to accommodate different radio standards. Moreover, many of the high performance RF components such as PAs and LNAs have a relatively low level of ancillary circuit integration. For example, voltage regulation circuits, temperature regulation circuits, control circuits and other circuits that are used for control and optimization of the operation of the PA are often not integrated into a same die with the PA but rather disposed as discrete components, on separate semiconductor substrates, within the module surrounding the PA die. It is well understood by most module designers that adding more components to the module increases cost, reduces yield and durability while resulting in an increase in module size. This effect is compounded when additional circuitry is used for each active RF component such as an RF switch, LNA, and PA.

Recent advances in SiGe BiCMOS technology have allowed for progressively higher levels of integration of high-performance RF components. For example, a high-performance 2.45 GHz PA for the 802.11b/g standard implemented in SiGe BICMOS technology can incorporate voltage and temperature regulation circuitry along with various power optimization and control schemes manifested in control circuitry. The benefit of such high levels of integration are well understood by the IC design community and include reduced module sizes, reduced cost, reduced assembly time, and increased yield and module longevity. Moreover, for PAs in particular, the robustness of the PA in tolerating of mismatch conditions to the antenna can be improved with voltage standing wave ratio (VSWR) sensing circuitry and PA output power sensing circuitry integrated into the PA chip. In this particular example, a determination of high VSWR might lead to the generation of a control signal to reduce power output and thereby protect one or more PA gain stages from over voltage conditions. Clearly, integration of this type of ancillary circuitry into the PA has the potential to increase PA performance and robustness with a minimum increase in the module size. In respect of LNAs, the integration of bias point control circuitry is important.

However, the usage of SiGe BiCMOS technology in the industry is currently limited. For example, for 5.8 GHz PAs, only a small number of manufacturers are utilizing SiGe, whereas several are utilizing GaAs or group III-V based technologies. The GaAs based technologies offer more gain per stage and lower losses in the RF signal path at 5.8 GHz. GaAs based technology, however, is often unsuitable for the integration of ancillary circuits for use with the GaAs based RF component. Voltage regulation, for example, may not economically be integrated into the GaAs based PA due to the lack of suitable elementary devices within the GaAs based technology. Therefore, in the context of a module, the module designer is compelled to add those additional circuits, or dies, for supporting of the GaAs based components. As mentioned previously, the addition of more components causes a detriment to the module size and cost.

A need therefore exists to for providing a compact RF module that supports a number of RF standards. It is therefore an object of the invention to provide a compact RF module that overcomes the limitations of the prior art by facilitating integration of multiple circuit components into a same module in order to support a number of RF standards.

### SUMMARY OF THE INVENTION

In accordance with the invention there is provided an electronic apparatus comprising a first integrated circuit semiconductor die containing at least one of a plurality of first signal conditioning circuits integrated within the first integrated semiconductor die for performing at least a first signal conditioning function on a signal propagating along at least a first signal path.

There is also provided a second integrated circuit semiconductor die which contains at least one of a plurality of second signal conditioning circuits integrated within the second integrated circuit die for performing at least a second signal conditioning function on a signal propagating along at least a second signal path other than the at least one of plurality of first signal paths.

Also integrated within the first integrated circuit die is a first ancillary circuit, which is electrically coupled to the at least one of the plurality of first signal conditioning circuits for other than performing the at least first signal conditioning function, and electrically coupled to the second integrated circuit semiconductor die for other than performing the at least a second signal conditioning function, and for use by at least one of the plurality of first signal conditioning circuits and at least one of the plurality of second conditioning circuits during operation thereof. There is also provided at least a substrate for supporting the first and second integrated circuit semiconductor dies.

In a second embodiment, the invention is an electronic apparatus comprising, a first integrated circuit semiconductor die which provides at least one of a plurality of first signal conditioning circuits integrated within the first integrated semiconductor die, first signal conditioning circuits for performing at least a first signal conditioning function on a signal propagating along at least a first signal path on the first integrated circuit semiconductor die.

Also having within the first integrated circuit semiconductor die a first ancillary circuit, which is electrically coupled to at least one of the plurality of first signal conditioning circuits for other than performing the at least first signal conditioning function and further having a first interface port electrically coupled to the first ancillary. circuit. The first integrated circuit semiconductor die other than requiring additional circuitry for use in performing the at least a first signal conditioning function.

Further providing a second integrated circuit semiconductor die containing at least one of a plurality of second signal conditioning circuits integrated within the second integrated circuit die for performing at least a second signal conditioning function on a signal propagating along at least a second signal path, said second signal path other than the at least one of plurality of first signal paths. The second integrated circuit semiconductor die also containing a second interface port electrically coupled to the at least one of the plurality of second signal conditioning circuits such that the second integrated circuit performs at least one of the plurality of second signal conditioning functions when the second interface port is electrically coupled to the first interface port. The coupling of the interface port therein providing electrical coupling of the first ancillary circuit disposed on the first integrated circuit die to the at least one of the plurality of second signal conditioning circuits.

In a further embodiment of the invention a method of designing a circuit for reducing crosstalk is outlined comprising the steps of providing a first signal conditioning circuit design and a second signal conditioning circuit design. The first signal conditioning circuit design implemented within a first semiconductor die along with a first portion of the second signal conditioning circuit design. The second portion of the second signal conditioning circuit design is implemented within in a second semiconductor die.

Also provided is a means within each of the first and second semiconductor die for implementing an electrical interconnection between the first and second semiconductor die so as to complete the second signal conditioning circuit design using at least the first and second portions of the second signal conditioning circuit.

Advantageously the invention whilst providing a means for supporting multiple RF standards in a module with reduced power consumption, also provides a means of reducing the crosstalk present within such a module by separating the ancillary circuit from the multiple signal conditioning die. Advantageously this approach also reduces thermal feedback effects.

### BRIEF DESCRIPTION OF THE DRAWINGS

Exemplary embodiments of the invention will now be described in conjunction with the following drawings, in which:

FIG. 1 illustrates a typical configuration for a multi-standard bidirectional microwave device.

FIG. 2 illustrates a prior art embodiment of a multi-standard amplifier module using discrete semiconductor devices or multiple semiconductor circuits integrated within a module.

FIG. 3 illustrates a first embodiment of the invention wherein all control circuitry for a multi-standard RF amplifier is integrated to a single semiconductor circuit.

FIG. 4 illustrates the operation of the first embodiment within a multi-standard apparatus wherein the control functions are integrated into the same semiconductor circuit as one of the signal conditioning circuits.

### DETAILED DESCRIPTION OF THE DRAWINGS

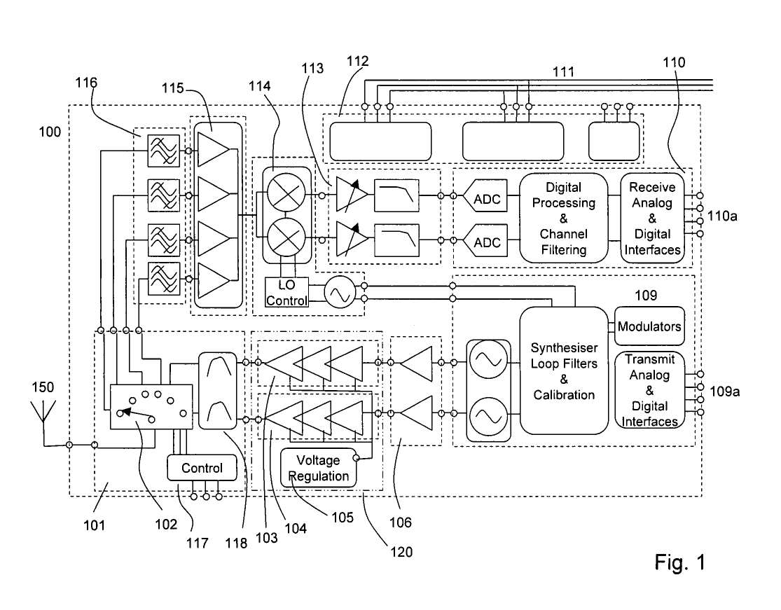

FIG. 1 illustrates a typical configuration for a multi-standard bidirectional microwave wireless device 100. Such a device for example is a quad-band cellular telephone designed to provide a user with a single cellular device operating on two protocols, GPRS and GSM. Each of these already requires the use of two frequencies and new standards/protocols are anticipated as the demands of the user and carriers for the provision of services over wireless networks increase. As such the module is operating at 850 MHz, 950 MHz, 1850 MHz and 1950 MHz. Alternatively, the wireless device 100 is addressing multiple IEEE 802 protocols, such as 802.11a with a centre frequency of 5.8 GHz, and two different standards at the same center frequency of 2.45 GHz, but with different digital protocols, known as 802.11b and 802.11g.

Shown in FIG. 1 is a multi-standard wireless device 100, which has externally connected an antenna 150. Considering, firstly, the receipt path of the wireless device 100 then the received RF signal from the antenna 150 is electrically coupled to an electrical switch 102 within a transmit/receive switching module 101. The electrical switch 102 defining whether the wireless device 100 is transmitting or receiving information through the antenna 150. In the receipt mode, electrical switch 102 is connected to an array of filtering elements 116. Only one of the array of filtering elements 116 is electrically coupled in this embodiment as the wireless device described is operable in only one protocol standard at any specific time. The received RF signal is therefore fed via the appropriate filtering element 116 to a first gain stage 115 such that a wide range of received RF signal powers are boosted and an approximately constant RF power is coupled to the subsequent chain of RF electronics.

The boosted RF signal is then down-converted from RF to an intermediate frequency (IF) by mixing with a local oscillator signal within the mixing block 114. From the mixing block 114 the down-converted IF is then fed into a variable gain stage 113 with low pass filtering such that the required IF data is then electrically coupled to the front-end analog-to-digital converter devices within the digital receive processing and interface block 110. Within the digital receive processing and interface block 110 the digitized data received is processed, which can include decryption, and then converted to the appropriate digital and analog interface signals for forward communication from the wireless device at port 110a. In the example of a cellular telephone examples of such analog/digital receive interfaces are an audio loudspeaker and USB interface respectfully, but others might be evident to one skilled in the art.

In communication with the receive electronics path is also a communications circuit block 112 which interfaces to a data bus 111 allowing the wireless device to be updated with changes in protocols, interface protocols etc.

Now considering the transmit path then the wireless device 100 receives an input signal at one of the input ports 109a. Means of providing such an input signal including a microphone, cellular telephone keypad for text messaging, email etc, USB device, camera, and music player such as an MP3 device. Information received at one of the input ports 109a is then processed according to the defined protocols of the wireless device, and the cellular infrastructure it is currently operating on. Such processing including the generation of appropriate transmission frequencies, modulation overlay and filtering, all of which are undertaken within the transmission-encoding block 109. The output ports of the transmission encoding block 109 are coupled to a first transmit gain block 106 which boosts the microwave signals from their as generated values to those acceptable to the input stage of the following power amplifier stage 120. As shown the wireless device 100 has two parallel paths of transmission signal generation in the IF/RF domain, these are typically GSM and GPRS although other combinations could be necessary to meet national and international standards.

The power amplifier stage 120 is shown comprising two parallel power amplifiers 103 and 104, which are electrically, coupled to a voltage regulator 105 to allow or the wider power supply rail limits that generally exist within portable devices. Each of the parallel amplifiers 103 and 104 is electrically coupled to a filter within a filter block 118, said filter block 118 electrically connected to the electrical switch 102. This completes the connections of the electrical switch 102 with four receive paths and two transmit paths, the electrical switch 102 thereby connecting the appropriate electronics path for the wireless protocol currently in use and switching the wireless device 100 between transmitting and receiving information.

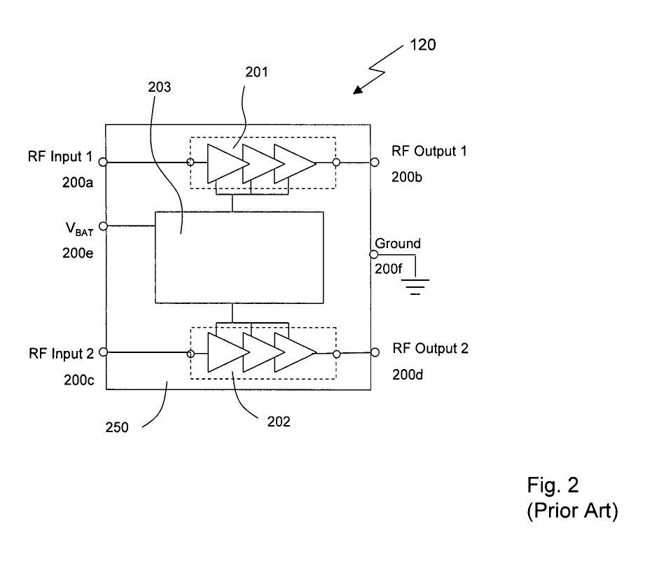

FIG. 2 illustrates a prior art integration of components into a module 200 which could form part of a wireless device 100 of FIG. 1. As can be seen from FIG. 1 the transmit and receive paths of a multi-band wireless device 100 have significant portions wherein electronics are paralleled. Disposed within the module 200 is a first signal conditioning circuit 201, a second signal conditioning circuit 202 and a voltage regulator circuit 203. The first signal conditioning circuit is disposed between a first RF signal input port 200a and a first RF signal output port 200b. The second signal conditioning circuit is disposed between a second RF signal input port 200c and a second RF signal output port 200d. A regulated supply voltage is provided to both the first and second signal conditioning circuits from the voltage regulator circuit 203, which is disposed on a different semiconductor substrate than the first and second signal conditioning circuits, 201 and 202. A supply voltage provided to the regulator circuit 203 is supplied in a handheld application from a battery (not shown) through a positive supply voltage input port 200e and through a ground port 200f. The first and second signal conditioning circuits are also coupled to the ground port 200f.

The voltage regulator circuit 203 is disposed as the third component of this module 200. Typically, the voltage regulation properties of the regulator circuit 203 are not optimized for operating with either the first or the second signal conditioning circuits in order to save on module cost 200. But, a trade-off in the module 200 specifications allows for use of a single regulator circuit 203 for regulating the supply voltage to both signal conditioning circuits. Providing a separate voltage regulator for each signal conditioning circuit adds another semiconductor substrate to the module 200 and results in an increased module cost.

For example, the module 200 shown in FIG. 2 is for use in cellular telephones, such as shown the power amplifier stage 120 in the preceding FIG. 1, where two cellular band power amplifier circuits (PAs) are incorporated into the same module as the first signal conditioning circuits 201, the power amplifier 103 of FIG. 1, and the second signal conditioning circuits 202, and the power amplifier 104 of FIG. 1. In such a module, the voltage regulation circuit is typically silicon-based and disposed onto a common ceramic carrier (not shown) with power amplifier modules which are generally of different types, such as SiGe or GaAs based PAs. It is not uncommon to find that the module size is determined by the area required for the ancillary circuits, such as the voltage regulation circuit 203, rather than by the area required by core RF components, such as the PAs.

Referring to the prior art module illustrated in FIG. 2, all circuits included in the module are disposed as discrete components. Unfortunately, this leads to progressively larger and more expensive modules as functionality and performance are increased. A further disadvantage of the technology lies in the additional assembly cost and additional assembly time associated with placing and wiring these numerous circuits and components within the module 200. It is well understood that in designing and manufacturing of the module, the area requirements grow in proportionality to the number of circuits and components used. Furthermore, the probability of manufacturing errors and defects increases in proportion to the number of circuits and components required in the design.

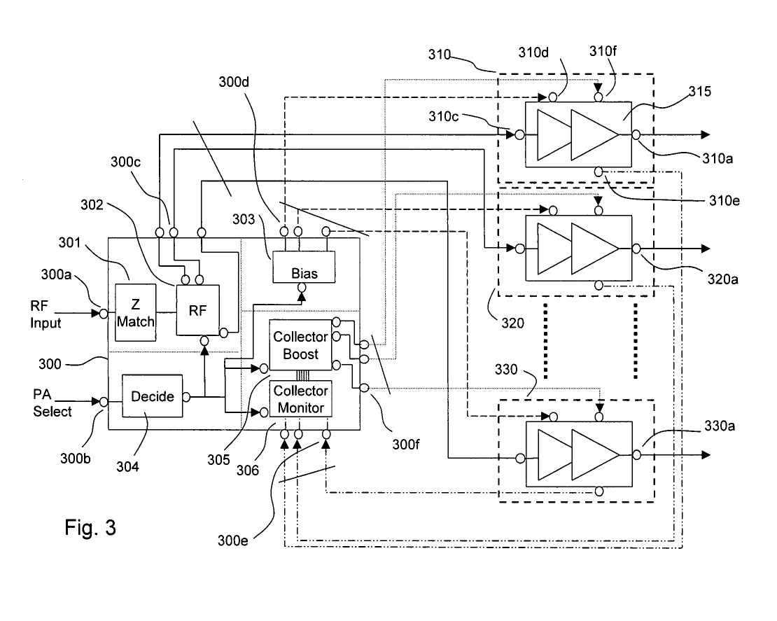

Referring to FIG. 3, a first embodiment of the invention is shown which addresses the requirements for increased functionality, integration and lower cost in high volume, cost sensitive applications such as cellular telephones. The embodiment as shown is an RF receiver quad-amplifier stage 115, which is in the receiver path of a wireless device 100.

Shown is a microwave module 300, which receives at an RF input port 300a a microwave signal to be processed signal conditioning stages 310 to 330. As shown within the embodiment for simplicity all the signal-conditioning stages 310 to 330 are shown as amplifier stages, and each is further shown requiring three input signals provided directly from within the microwave module 300. Considering signal conditioning stage 310, which comprises amplifier cell 315, these input signals are the RF input signal at RF input port 310c, a bias control signal applied to bias port 310d, and a collector-boost signal applied to booster port 310f.

Propagating from the signal conditioning stage 310 is the conditioned RF signal, coupled to the RF output port 310a, and a power boost signal at boost output port 310e. Considering these connections from the signal conditioning stage one by one we shall now describe their linking to the microwave module 300 and it's internal construction and operation.

Considering firstly the RF input port 310c this is electrically coupled to an RF output port 300c of the microwave module 300, which is one of a plurality of RF output ports of the microwave module 300 which are electrically coupled to the RF input ports of all signal-conditioning stages 310, 320 and 330. Internal to the microwave module 300 the RF output port 300c is coupled to an RF routing circuit 302. The RF routing circuit 302 which is electrically coupled at a port thereof to an impedance matching circuit 301, which is itself coupled to an RF input port 300a of the microwave module 300. Finally the RF routing circuit 302 is electrically coupled to a decision circuit 304, which is addressed with a PA select signal at port 300b of the microwave module 300.

In this manner the one of the potential plurality of signal conditioning circuits is selected by the decision circuit 304 in response to the data provided to port 300b. In the embodiment shown the data causes the RF switch circuit 302 to electrically couple the impedance matched RF input signal to the selected signal conditioning circuit 310, and therein deselecting all other RF ports.

Now considering the bias control signal applied to port 310d of the signal conditioning circuit this is electrically coupled to one of the bias output ports 300d. The plurality of bias output ports 300d are connected to a bias control and generation circuit 303, this electrical coupling providing the requisite bias control signal to the signal conditioning circuit 310. The bias control and generation circuit 303 is electrically coupled to the decision circuit 304 such that the bias control circuit is addressing the same signal conditioning circuit 301 as the RF switch circuit 301.

Turning now to the collector-boost signal applied to booster port 310f, the booster port 310f is electrically coupled to the collector boost output port 300f, an output port of the microwave module 300. The current boost circuit 305 provides current boost to the signal conditioning stage 310, so that the current boost is typically applied to a power amplifier only at high output powers to augment bias control signals. In common with other elements of the microwave circuit, the current boost circuit 305 is electrically coupled to the decision circuit 304 such that the correct port is active.

The collector boost circuit 305 is also shown coupled to a collector monitor circuit 306, which is itself is electrically coupled to a boost input port 300e of the microwave module 300. In this manner the signal conditioning circuit 310 may contain additional detection and decision circuitry, which monitors the operation of the signal conditioning circuit 310 and decides whether signal boost is required. If the decision is positive then a signal is communicated via output port 310a to the collector monitor circuit 306 and therein to the collector boost circuit 305. This triggers a boost current to be provided from the appropriate output port 300f to the signal conditioning circuit port 310f, thereby reducing power consumption of the overall circuitry, as current boost is not only provided as required but also only to the appropriate signal conditioning circuit. In common with other elements the collector monitor circuit 306 is electrically coupled to the decision circuit 304 so that it is monitoring the correct signal conditioning circuit.

The electronics within a cellular telephone 100, in common with other multi-standard wireless devices, may operate solely in a transmit mode or receive mode at any specific point in time rather than supporting simultaneous bidirectional communication. As such, the module 300 may optionally be a combination of the transmit gain stage 120 and the receiver quad-amplifier stage 115. Also as the wireless device 100 would typically be communicating with only one network at that specific point in time then only one signal conditioning circuit of the plurality is active. This advantageously allows for reduced footprint, reduced cost and component count in cost and size sensitive applications.

In alternate embodiments of the invention the signal conditioning circuits 310 to 330 may be a combination of conditioning circuits such as LNAs, PAs, mixers, and attenuators. It would also be evident to one skilled in the art that the “boost” may be provided by a temporary increase in the bias voltage applied to a section of the circuit, or a temporary increase in both bias current and bias voltage, such that for a short period of time, the amplifier is able to deal with a high peak signal without going into compression and thereby preserving linearity. The cost of this is a momentary increase in amplifier power consumption.

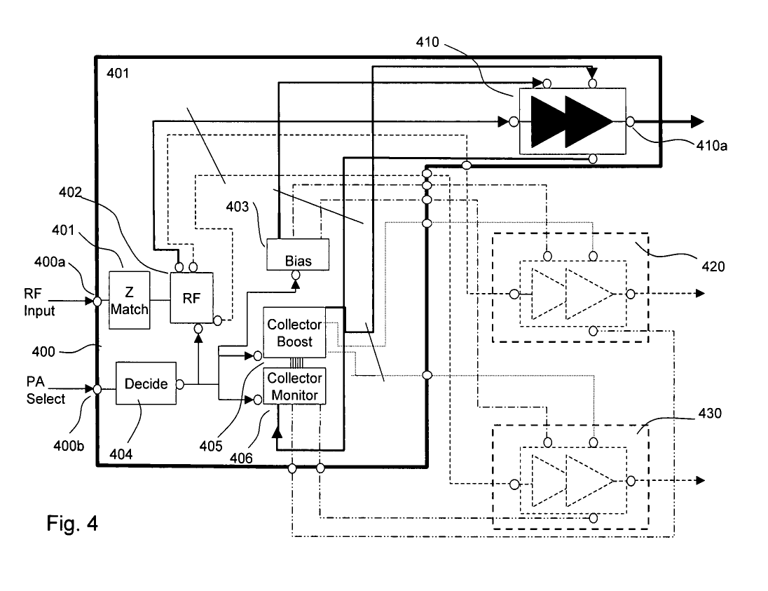

Referring to FIG. 4 shown is an embodiment of the invention wherein the functional integration of the elements within a wireless device 100 has been increased. Shown in FIG. 4 is essentially the same functional combination of circuit elements as in FIG. 3 so that the RF signal applied at port 400a sees an impedance matching circuit 401 and RF switch circuit 402 prior to electrically coupling with the appropriate signal conditioning circuit of 410 to 430. Each of the signal conditioning circuits 410 to 430 is electrically coupled to a bias control circuit 403, collector boost circuit 405 and collector monitor circuit 406. The RF switch circuit 402, bias control circuit 403, collector boost circuit 405, and collector monitor circuit 406 are all electrically coupled to a decision circuit 404 which is electrically coupled to an input port 400b of the overall module 400. In the embodiment shown all of these functional elements are integrated with one of the signal conditioning circuits, namely 310. The resulting microwave module 400 therefore comprises all of the active control and monitoring functions for a signal conditioning circuit of a wireless device 100.

Advantageously this reduces the footprint, cost and complexity of the manufacture of such wireless devices 100. Advantageously such a microwave module 400 is optionally expanded to integrate additional signal conditioning circuits or these are assembled as additional discrete elements or integrated circuits with the microwave module 400 according to the demands of the design of the wireless device 100.

The microwave module 400 is optionally assembled using a variety of discrete elements, using techniques such as flip-chip assembly of bare die to a common electrical interconnect and mechanical base, or through thick- or thin-film hybrid assembly approaches. Significant benefit of the invention occurs when the multiple matching, control, decision and monitoring circuits 401 to 406 are implemented in the same semiconductor technology as one of the signal conditioning circuits, such as 410, to monolithically integrate all the elements.

It would be evident to one skilled in the art that the RF switch circuit 402 can be either an active or a passive function. For example, if the RF switch circuit 402 is a passive splitter then bias control circuit 403 may apply a bias to only one of the parallel signal conditioning circuits 410 to 430 so that for those signal conditioning blocks not biased they are effectively turned off and act effectively as either attenuator blocks or impendence mismatched blocks to effectively block the input RF signal on these paths. In effect, the RF signal is routed without the requirement for an active switch.

It would also be evident to one skilled in the art that the RF switch circuit 402 can be a multiple port filtering network; wherein a signal is coupled to the appropriate port based upon frequency.

For a typical wireless device 100 operating on the IEEE 802.11a/b/g standards it is possible to implement the preceding embodiments using a SiGe BiCMOS manufacturing technology. However, other suitable manufacturing technologies for integration of the ancillary circuitry may also be supported. Alternate embodiments of the invention can advantageously allow for integration of silicon or silicon-germanium based technologies with other technologies such as GaAs, InP, and GaN that do not support a similar level of component integration.

Therefore considering the two examples given for FIG. 1 in the first case of a quad-band cellular telephone operating at 850 MHz, 950 MHz, 1850 MHz and 1950 MHz, the first two channels (850 MHz, 950 MHz) are integrated into the same semiconductor die as the multiple matching, control, decision and monitoring circuits 401 to 406. According to another embodiment all of the quad-band signal conditioning circuits (operating at 850 MHz, 950 MHz, 1850 MHz, and 1950 MHz) are integrated into a single die with the multiple matching, control, decision and monitoring circuits 401 to 406. This is feasible with SiGe based semiconductor circuits.

Considering the second example, the two signal conditioning circuits operating

2.45 GHz for the IEEE 802.11b and IEEE 802.11g protocols are optionally integrated in the same semiconductor die as the multiple matching, control, decision and monitoring circuits 401 to 406. In this scenario the signal conditioning circuit or circuits supporting the transmit/receive of the IEEE 802.11a at 5.8 GHz could be a GaAs amplifier electrically coupled to, for example, the SiGe BiCMOS microwave module. Full monolithic integration of the multiple signal conditioning circuits, matching, control, decision and monitoring circuits is supported in semiconductor materials such as SiGe.

Numerous other embodiments may be envisaged without departing from the spirit or scope of the invention.

What is claimed is:

1. An electronic apparatus comprising:
a first integrated circuit semiconductor die comprising:
a first signal conditioning circuit integrated within the first integrated semiconductor die for performing a first signal conditioning function on a signal propagating along a first signal path and comprising a first control portion;
a second integrated circuit semiconductor die comprising:
a second signal conditioning circuit integrated within the second integrated circuit die for performing a second signal conditioning function on a signal propagating along a second signal path other than the first signal path;
a first ancillary circuit comprising at least a portion of the first control portion integrated within the first integrated circuit die and electrically coupled to the first signal conditioning circuit for other than performing the first signal conditioning function, and electrically coupled to the second integrated circuit semiconductor die for other than performing the second signal conditioning function, and for use by each of the first signal conditioning circuit and the second signal conditioning circuit during operation thereof, wherein only one of the first signal conditioning circuit and the second signal conditioning circuit is for operating at any instant; and
at least a substrate for supporting the first and second integrated circuit semiconductor dies.

2. An electronic apparatus according to claim 1;
wherein the first ancillary circuit additionally comprises a first control port, the first control port for receiving a first control signal, wherein the first control signal in use establishing the one of the first signal conditioning circuit and the second signal conditioning circuit in operation.

3. An electronic apparatus according to claim 1;
wherein the first ancillary circuit additionally comprises a detection circuit; the detection circuit for monitoring one of the first signal conditioning circuit and second signal conditioning circuit and determining therefrom the one of the first signal conditioning circuit and the second signal conditioning circuit to be in operation.

4. An electronic apparatus according to claim 1;
wherein the first ancillary circuit additionally comprises a detection circuit;
the detection circuit for monitoring the one of the first signal conditioning circuit and second signal conditioning circuit and determining therefrom whether the one of the first signal conditioning circuit and second signal conditioning circuit is approaching a compression point of a conditioned signal of the electronic apparatus.

5. An electronic apparatus according to claim 4;
where the one of the first signal conditioning circuit and second signal conditioning circuit is biased to provide a boost to the one of the first signal conditioning circuit and second signal conditioning circuit; such that
the one of the first signal conditioning circuit and second signal conditioning circuit does not enter compression.

6. An electronic apparatus according to claim 5;
wherein the boost applied to the one of the first signal conditioning circuit and second signal conditioning circuit is at least one of bias current or bias voltage.

7. An electronic apparatus according to claim 1;
wherein the second integrated circuit die is manufactured using a first semiconductor process and utilizes a first silicon based technology.

8. An electronic apparatus according to claim 7;
wherein the first integrated circuit die is manufactured using a second semiconductor process and utilizes an other than first silicon based technology.

9. An electronic apparatus according to claim 1;
wherein the second integrated circuit die is derived from a first semiconductor wafer comprised of one of Si, SiGe, GaAs, InP, and GaN.

10. An electronic apparatus according to claim 9;
wherein the first integrated circuit die is derived from a second semiconductor wafer formed of another of Si, SiGe, GaAs, InP, and GaN.

11. An electronic apparatus according to claim 9;
wherein the first integrated circuit die is derived from a first semiconductor wafer of the one of Si, SiGe, GaAs, InP, and GaN using a second semiconductor process that is different from that used to manufacture the second integrated circuit die.

12. An electronic apparatus according to claim 1;
wherein at least one of the first and second integrated circuit die is manufactured using a BiCMOS process.

13. An electronic apparatus according to claim 12;
wherein at least one of first and second integrated circuit die comprises SiGe epitaxial technology.

14. An electronic apparatus according to claim 1;
wherein the second integrated circuit die is manufactured using a second semiconductor process that is different from that used to manufacture the first integrated circuit die.

15. An electronic apparatus according to claim 1;
wherein the first signal conditioning function and the second signal conditioning function provide similar signal conditioning operations.

16. An electronic apparatus according to claim 1;
wherein the first signal conditioning circuit comprises at least a power amplifier circuit and where the function of the first signal conditioning circuit is for amplifying of an input signal using the at least a power amplifier circuit.

17. An electronic apparatus according to claim 1;
wherein the second signal conditioning circuit comprises at least a power amplifier circuit and where the function of the second signal conditioning circuit is for amplifying of an input signal using the at least a power amplifier circuit, and
wherein the first ancillary circuit comprises at least one of an impedance matching circuit, an electrical switch, a bias control circuit, and a collector-boost circuit.

18. An electronic apparatus according to claim 1;
additionally comprising a means to selectively interface the first ancillary circuit with one of the plurality of first signal conditioning circuits or plurality of second signal conditioning circuits, and
wherein the first ancillary circuit comprises at least one of an impedance matching circuit, an electrical switch, a bias control circuit, and a collector-boost circuit.

19. An electronic apparatus according to claim 17;
wherein the first ancillary circuit additionally comprising a decision circuit.

20. An electronic apparatus according to claim 19;
wherein the decision circuit is electrically coupled to an interface, the interface for supporting data defining the one of the plurality of first signal conditioning circuits or plurality of second signal conditioning circuits to be in operation.

21. An electronic apparatus according to claim 19;
wherein the decision circuit selects the one of the plurality of first conditioning circuits or one of the plurality of second signal conditioning circuits based upon the signal coupled to the electronic apparatus for conditioning by the at least one of the plurality of first conditioning circuits or plurality of second signal conditioning circuits.

22. An electronic apparatus according to claim 21;
wherein the decision circuit provides at least one control signal to the first ancillary circuit; such that
the first ancillary circuit enables operation of the selected one of first and second signal conditioning circuits.

23. An electronic apparatus according to claim 1;
wherein the first ancillary circuit comprises at least one of voltage regulation circuitry and temperature control circuitry.

24. An electronic apparatus according to claim 1;
wherein the first integrated circuit die comprises a first interface port connected to the first ancillary circuit, the second integrated circuit comprises a second interface port, the second integrated circuit for being connected to the first ancillary circuit using the first and second interface ports.

25. An electronic apparatus according to claim 1;
wherein the second signal conditioning circuit is for performing the second signal conditioning function in conjunction with operation of the first ancillary circuit.

26. An electronic apparatus according to claim 1;
wherein the substrate is at least one of a semiconductor material, sapphire, aluminum oxide, aluminum nitride, beryllium oxide, copper-tungsten, copper-molybdenum, substantially an iron-nickel-cobalt alloy, and part of a housing.

27. An electronic apparatus comprising:
a first integrated circuit semiconductor die comprising:
a first signal conditioning circuit integrated within the first integrated semiconductor die for performing a first signal conditioning function on a signal propagating along a first signal path and comprising a first control portion;
a first ancillary circuit electrically coupled to the first signal conditioning circuit for other than performing the first signal conditioning function, a first interface port electrically coupled to the first ancillary circuit;
wherein the first integrated circuit semiconductor die other than requiring additional circuitry for use in performing the at least a first signal conditioning function;
a second integrated circuit semiconductor die comprising:
a second signal conditioning circuit integrated within the second integrated circuit die for performing a second signal conditioning function on a signal propagating along a second signal path other than the first signal path;
a second interface port electrically coupled to the second signal conditioning circuit;
wherein the second integrated circuit performing the second signal conditioning functions when the second interface port is electrically coupled to the first interface port therein providing electrical coupling of the first ancillary circuit disposed on the first integrated circuit die to the second signal conditioning circuits,
a substrate for supporting the first and second integrated circuit semiconductor dies;
wherein the first ancillary circuit in operation with only one of the first signal conditioning circuit and second signal conditioning circuit at any instant.

28. An electronic apparatus according to claim 27;
wherein the first ancillary circuit additionally comprises a first control port, the first control port for receiving a first control signal wherein the first control signal in use establishing the one of the first signal conditioning circuit and the second signal conditioning circuit in operation.

29. An electronic apparatus according to claim 27;
wherein the first ancillary circuit additionally comprises a detection circuit; the detection circuit for monitoring the first signal conditioning circuit and second signal conditioning circuit and determining therefrom the one of the first signal conditioning circuit and the second signal conditioning circuit to be in operation.

30. An electronic apparatus according to claim 27;
wherein the first ancillary circuit additionally comprises a detection circuit;
the detection circuit for monitoring the one of the first signal conditioning circuit and second signal conditioning circuit and determining therefrom whether the one of the first signal conditioning circuit and second signal conditioning circuit is approaching a compression point of a conditioned signal of the electronic apparatus.

31. An electronic apparatus according to claim 30;
where the one of the first signal conditioning circuit and second signal conditioning circuit is biased to provide a boost to the one of the first signal conditioning circuit and second signal conditioning circuit; such that
the one of the first signal conditioning circuit and second signal conditioning circuit does not enter compression.

32. An electronic apparatus according to claim 31;
wherein the boost applied to the one of the first signal conditioning circuit and second signal conditioning circuit is at least one of bias current or bias voltage.

33. An electronic apparatus according to claim 27;
wherein the first integrated circuit die is manufactured using a first semiconductor process and utilizes a first silicon based technology.

34. An electronic apparatus according to claim 33;
wherein the second integrated circuit die is manufactured using a second semiconductor process and utilizes an other than first silicon based technology.

35. An electronic apparatus according to claim 27;
wherein the first integrated circuit die is derived from a first semiconductor wafer comprised of one of Si, SiGe, GaAs, InP, and GaN.

36. An electronic apparatus according to claim 35;
wherein the second integrated circuit die is derived from a second semiconductor wafer the other one of Si, SiGe, GaAs, InP, and GaN.

37. An electronic apparatus according to claim 35;
wherein the second integrated circuit die is derived from a second semiconductor wafer of the one of Si, SiGe, GaAs, InP, and GaN using a second semiconductor process that is different from that used to manufacture the first integrated circuit die.

38. An electronic apparatus according to claim 27;
wherein the first integrated circuit die is manufactured using a BiCMOS process.

39. An electronic apparatus according to claim 38;
wherein the first integrated circuit die comprises SiGe.

40. An electronic apparatus according to claim 27;
wherein the second integrated circuit die is manufactured using a second semiconductor process that is different from that used to manufacture the first integrated circuit die.

41. An electronic apparatus according to claim 27;
wherein the first signal conditioning function and the second signal conditioning function provide similar signal conditioning operations.

42. An electronic apparatus according to claim 27;
additionally comprising a means to selectively interface the first ancillary circuit with one of the plurality of first signal conditioning circuits or plurality of second signal conditioning circuits.

43. An electronic apparatus according to claim 42;
wherein the first ancillary circuit additionally comprising a decision circuit.

44. An electronic apparatus according to claim 43;
wherein the decision circuit is electrically coupled to an interface, the interface for supporting data defining the one of the plurality of first signal conditioning circuits or plurality of second signal conditioning circuits.

45. An electronic apparatus according to claim 43;
wherein the decision circuit selects the one of the plurality of first conditioning circuits or one of the plurality of second signal conditioning circuits based upon the signal coupled to the electronic apparatus for conditioning by the at least one of the plurality of first conditioning circuits or plurality of second signal conditioning circuits.

46. A method of designing a circuit for reducing power consumption comprising the steps of:
providing a first signal conditioning circuit design;
providing a second signal conditioning circuit design;
implementing the first signal conditioning circuit design comprising a first control portion within a first semiconductor die;
implementing a first portion of the second signal conditioning circuit design in the first semiconductor die, the first portion at least comprising the first control portion;
implementing a second portion of the second signal conditioning circuit design in a second semiconductor die;
providing within each of the first and second dies an interface for implementing an electrical interconnection between the first and second dies so as to complete the second signal conditioning circuit;
wherein the first control portion controls one of the first signal conditioning circuit and second conditioning circuit at any instant.

47. A method according to claim 46;
wherein the first ancillary circuit further comprises circuitry such that the first control portion controls only one of the first signal conditioning circuit and second signal conditioning circuit.

48. A method according to claim 46;
wherein the first semiconductor die comprises a first signal path.

49. A method according to claim 48;
wherein the second semiconductor die comprises a second signal path that is other than the first signal path and in approximate RF isolation therefrom.

50. A method according to claim 46;
wherein the second semiconductor die is manufactured using a more expensive semiconductor process than that used for manufacturing of the first semiconductor die.

51. A method according to claim 46;
wherein the first portion of the second signal conditioning circuit is more cost effectively implemented in the first semiconductor die.

52. A method according to claim 46;
wherein prior to the step of implementing the first portion of the second signal conditioning circuit in the first semiconductor die, comprises the step of partitioning of the second signal conditioning circuit into the first portion and the second portion.
